(19) United States
(12) Patent Application Publication
(10) Pub. No.: US 2008/0123246 A1
(43) Pub. Date: May 29, 2008

(54) Semiconductor device and method for fabricating the same

(75) Inventor: Jeong Su PARK, Gyeyang-gu (KR)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: Dongbu HiTek Co., Ltd.

(21) Appl. No.: 11/976,693

(22) Filed: Oct. 26, 2007

(30) Foreign Application Priority Data
Nov. 27, 2006 (KR) 10-2006-0117381

(51) Int. Cl. H01L 21/64; H01G 4/08

(52) U.S. Cl. 361/305; 438/656; 257/E21.52

(57) ABSTRACT

A semiconductor device having a metal/insulator/metal (MIM) structure and a method for fabricating the same are provided. The semiconductor device includes a lower structure layer including a metal wiring; and an MIM stack on the lower structure layer; wherein the MIM stack includes a lower metal electrode film formed on a substrate including the lower structure layer, a multi-layer dielectric film including a first insulating film and a second insulating film formed on the lower metal electrode film, and an upper metal electrode film formed on the multi-layer dielectric film.

This application claims the benefit of priority to Korean Patent Application No. 10-2006-0117381, filed on Nov. 27, 2006, the entire contents of which are incorporated herewith by reference.

### BACKGROUND

1. Technical Field

The present invention relates to a semiconductor device. More particularly, the present invention relates to a semiconductor device having a metal/insulator/metal (MIM) structure, and a method for fabricating the same.

2. Related Art

A memory element of a semiconductor device, such as a dynamic random access memory (DRAM), stores predetermined data in a capacitor.

The capacitor comprises a structure of a dielectric film, i.e., a storage node, interposed between electrodes, i.e., plate nodes.

Recently, as the semiconductor device becomes highly integrated, a memory cell area constituting the memory element is reduced and an operating voltage of the semiconductor device tends to be low.

Therefore, the projection area of the capacitor, which is one of the components of the memory element, is reduced. However, despite the reduction of the projection area, the capacitor needs to secure a sufficient amount of charge required for the operation of the memory element.

When the amount of charge is not sufficient, many problems, such as soft error in the memory element, short refresh time, and the like, would occur.

The amount of charge Q can be represented as Q=CV, where C denotes the capacitance of the capacitor, and V denotes the operating voltage of the capacitor. Accordingly, the amount of charge Q is determined by operating voltage V applied to the capacitor and capacitance C of the capacitor.

However, since the memory element is highly integrated and, at the same time, the operating voltage is gradually reduced, the only way to accrue a specific amount of charge in the capacitor is to increase the capacitance of the capacitor.

Accordingly, a sufficient capacitance needs to be secured even when the projection area of the capacitor is small. Capacitance C can be represented by the following equation 1.

C=∈·S/d [Equation 1]

In equation 1, C represents capacitance, E denotes permittivity of the dielectric film, S denotes an area of the electrode plates, and d denotes a gap between the electrode plates or a thickness of the dielectric film.

According to equation 1, capacitance C is directly proportional to permittivity ∈ of the dielectric film and area S of the capacitor, and is inversely proportional to thickness d of the dielectric film between the electrode plates.

Accordingly, in order to obtain a high capacitance for the capacitor, one may increase the area of the electrodes, use a dielectric film with high permittivity, or reduce the gap between the electrodes, that is, minimize the thickness of the dielectric film.

Meanwhile, a capacitor having a metal-insulator-metal (MIM) structure has been used due to the high integration and high performance requirements of the semiconductor device.

FIG. 1a shows a semiconductor device having a MIM structure, according to the related art.

In the state having a lower structure, such as a metal wiring with a TiN/Al/TiN structure, etc., the MIM structure is formed by stacking TiN 11/SiN 12/TiN 13.

FIG. 1b is an enlarged cross-sectional view of a portion represented by a circle in FIG. 1a. In order to form the MIM structure, when an etching on the MIM structure formed of stacked films of TiN 11/SiN 12/TiN 13 is completed, an insulating film of SiN 12 is left on TiN 11 layer.

Therefore, in order to increase the capacitance of the capacitor, one may choose to reduce the thickness of the MIM structure. Reducing the thickness of the MIM structure can be achieved by optimizing the fabrication process.

However, when the thickness of the MIM structure is lowered, it is possible that, during an etching process, the metal will be exposed at a locally thin portion of the MIM structure. At this time, a portion of the etched metal is attached to side walls of the MIM structure during the etching process using sputtering, making it possible to have a bad effect to the semiconductor device. Further, layers below the MIM structure may be damaged during etching process. Therefore, the conventional techniques for increasing the capacitance of a capacitor by reducing the thickness thereof is limited.

### SUMMARY

In one embodiment, the semiconductor device includes a lower structure layer including a metal wiring; and a MIM stack on the lower structure layer; wherein the MIM stack includes a lower metal electrode film formed on a substrate including the lower structure layer, a multi-layer dielectric film including a first insulating film and a second insulating film formed on the lower metal electrode film, and an upper metal electrode film formed on the multi-dielectric film.

In one embodiment, the method for fabricating the semiconductor device includes forming a lower metal electrode film on a substrate having a predetermined lower structure; forming a multi-layer dielectric film including a first insulating film and a second insulating film formed on the lower metal electrode film; forming an upper metal electrode film on the multi-layer dielectric film; and etching the upper metal electrode film and the multi-layer dielectric film to form a metal/insulator/metal (MIM) structure.

### BRIEF DESCRIPTION OF THE DRAWINGS

In the drawings:

FIGS. 1a and 1b are cross-sectional views showing a semiconductor device including an MIM structure, according to the related art; and

FIG. 2 is a cross-sectional view illustrating a semiconductor device and a method for forming the same, according to an embodiment consistent with the present invention.

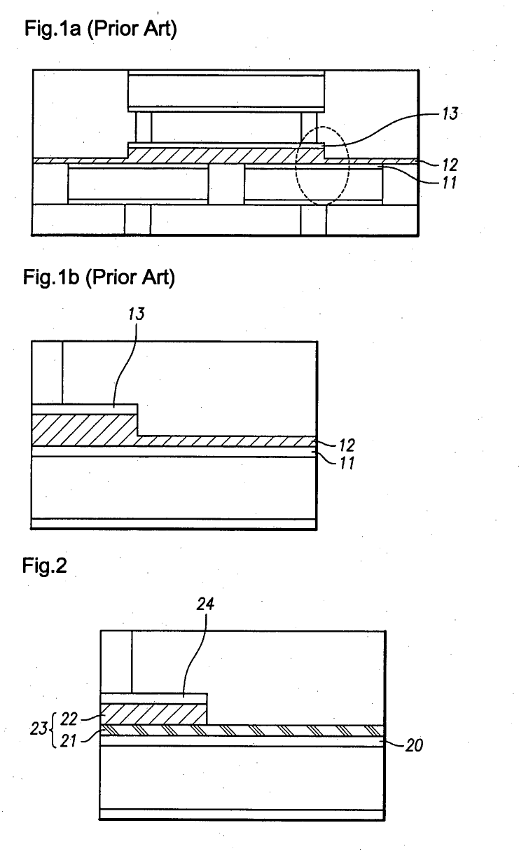

### DETAILED DESCRIPTION

Hereinafter, a semiconductor device and a method for fabricating the same, according to an embodiment consistent with the present invention, will be described in detail with reference to the accompanying drawings.

FIG. 2 is a cross-sectional view illustrating a semiconductor device and a method for fabricating the same, according to an embodiment consistent with the present invention.

As shown in FIG. 2, a lower structure layer including a metal wiring is formed. In one embodiment, the lower structure layer may be a TiN/Al/TiN structure.

Further, a lower metal electrode film 20 is formed on a substrate (not shown), on which the lower structure layer is formed. Lower metal electrode film 20 may be formed to have a thickness of about 550 Å to 650 Å. In one embodiment, lower metal electrode film 20 may comprise a TiN film.

Subsequently, a first insulating film 21 and a second insulating film 22 are sequentially formed on lower metal electrode film 20. In one embodiment, first insulating film 21 may be an oxide film having a thickness of about 70 Å to 100 Å, and may comprise SiO₂.

First insulating film 21 may serve as an etch stop layer. More specifically, first insulating film 21 may be a film for preventing the metal wiring from being exposed at a locally thin portion of the MIM structure. The locally thin portion is generated when performing an etching process on the MIM structure to reduce the thickness of the MIM structure. In other words, first insulating film 21 may be an etch stop layer for preventing the upper portion of the metal wiring, that is, the lower structure, from being exposed at a locally thin portion generated in an etching process performed on the MIM structure.

Also, a second insulating film 22 is formed on first insulating film 21 to have a thickness of about 250 Å to 370 Å. Second insulating film 22 may comprise SiN.

Consequently, a multi-layer dielectric film 23 including first insulating film 21 and second insulating film 22 is formed.

In one embodiment, second insulating film 22 may be formed using high permittivity materials other than SiN. That is, any one of a group consisting of a TiO₂ film, a HfO₂ film, a ZrO₂ film, a SrTiO₃ film, and a (Bi, (e)₄Ti₃O₁₂) film may be used.

Accordingly, the thickness of multi-layer dielectric film 23 can be controlled by means of first insulating film 21, which functions as an etch stop layer. Therefore, a capacitor of higher capacitance can be obtained.

In order words, first insulating film 21 is formed prior to the formation of second insulating film 22.

As discussed above, the formation of multi-layer dielectric film 23 makes it possible to prevent side walls of the MIM structure from being polluted by the etched metal generated in the etching process for forming the MIM structure. In one embodiment, the MIM etching process uses a metal sputtering. As a result, the problem of capacitor malfunctioning can be solved by preventing the pollution of the side walls of the MIM structure, as discussed above.

Also, even though new dielectric materials may be used, the fabricating process is not changed. The capacitor consistent with the present invention can still obtain a high capacitance.

After multi-layer dielectric film 23 is formed, an upper metal electrode film 24 is formed on multi-layer dielectric film 23. Therefore, a MIM stack is formed by sequentially stacking lower metal electrode film 20, multi-layer dielectric film 23, and upper metal electrode film 24.

Upper metal electrode film 24 may be formed to have a thickness of about 800 Å to 1200 Å and may comprise TiN. In other words, the thickness of upper metal electrode film 24 may be different from that of lower metal electrode film 20, but may comprise the same material, i.e., TiN, as lower metal electrode film 20.

After lower metal electrode film 20, multi-layer dielectric film 23, and upper metal electrode film 24 are sequentially formed, that is, the stacked film of TiN/SiN/SiO₂/TiN, an etching process may be performed on the stacked film to form a final MIM structure.

When performing the etching process for forming the MIM structure, an etching gas with good selectivity may be used for multi-layer dielectric film 23.

Among the layers of multi-layer dielectric film 23, the SiN of second insulating film 22 has a dielectric constant of about 6.5, and the SiO₂ of first insulating film 21 has a dielectric constant of about 3.9. In one embodiment, the etching gas with good selectivity of SiN and SiO₂ may be any one selected from the group consisting of CH₂ gas, F₂ gas, and a mixture of CH₂ gas and F₂ gas.

Then, as shown in FIG. 2, a first insulating film 21 comprising SiO₂, which functions as an etch stop layer for the upper area of the metal wiring, that is, the lower structure on the substrate, is left as is, when an etching process is performed on a portion of second insulating film 22 comprising SiN.

Accordingly, even when the thickness of multi-layer dielectric film 23 is lower than 640 Å, the etching and damaging at some upper portions of the metal wiring may be prevented.

Also, a higher capacitance can be obtained while lowering the thickness of multi-layer dielectric film 23.

It will be apparent to those skilled in the art that various modifications and variations can be made without departing from the spirit and/or scope of the present invention. Thus, it is intended that the present invention covers any modifications and variations consistent with the present invention.

As described above, the MIM structure includes an insulting film comprising SiO₂, which functions as an etch stop layer, such that multi-layer dielectric film 23 can be formed. Therefore, one may easily control the thickness of the dielectric film of the capacitor, thereby obtaining a high capacitance for the capacitor.

Also, even when the thickness of the dielectric film of the capacitor is lower than 640 Å, the problem of the side walls pollution due to the etched metal generated in the etching process may be solved. Therefore, malfunctioning of the MIM structure may be controlled, making it possible to improve the reliability of the semiconductor device.

What is claimed is:

1. A method for fabricating a semiconductor device, comprising:
forming a lower metal electrode film on a substrate having a predetermined lower structure;
forming a multi-layer dielectric film including a first insulating film and a second insulating film on the lower metal electrode film;
forming an upper metal electrode film on the multi-layer dielectric film; and
etching the upper metal electrode film and the multi-layer dielectric film to form a metal/insulator/metal (MIM) structure.

2. The method according to claim 1, wherein the upper metal electrode film comprises TiN.

3. The method according to claim 1, wherein the lower metal electrode film comprises TiN.

4. The method according to claim 1, wherein the first insulating film comprises SiO₂.

5. The method according to claim 1, wherein the second insulating film comprises SiN.

6. The method according to claim 1, wherein the second insulating film comprises any one of a TiO₂ film, a HfO₂ film, a ZrO₂ film, a SrTiO₃ film, and a (Bi, (e)₄Ti₃O₁₂) film having a high permittivity.

7. The method according to claim 1, wherein the upper metal electrode film has a thickness of about 550 Å to 650 Å, the first insulating film has a thickness of about 70 Å to 100 Å, the second insulating film has a thickness of about 250 Å to 370 Å, and the upper metal electrode has a thickness of about 800 Å to 1200 Å.

8. The method according to claim 1, wherein the etching step uses an etching gas including any one of a CH₂ gas, a F₂ gas, and a mixture of CH₂ gas and F₂ gas.

9. A semiconductor device comprising:
a lower structure layer including a metal wiring; and
a metal/insulator/metal (MIM) stack formed on the lower structure layer; wherein
the MIM stack comprises a lower metal electrode film formed on a substrate including the lower structure layer, a multi-layer dielectric film including a first insulating film and a second insulating film formed on the lower metal electrode film, and an upper metal electrode film formed on the multi-layer dielectric film.

10. The semiconductor device according to claim 9, wherein in the lower metal electrode film comprises TiN, the multi-layer dielectric film comprises SiO₂/SiN, and the upper metal electrode film comprises TiN.
